(19) United States
(12) Patent Application Publication
(10) Pub. No.: US 2026/0251980 A1
(43) Pub. Date: Aug. 27, 2026

(54) Modulation of X-Ray Beam Intensity

(71) Applicant: LumArray, Inc., Somerville, MA (US)

(72) Inventors: Henry I. Smith, Sudbury, MA (US); Timothy A. Savas, Salem, MA (US)

(73) Assignee: LumArray, Inc., Somerville, MA (US)

(21) Appl. No.: 19/532,141

(22) Filed: Feb. 6, 2026

Related U.S. Application Data
(60) Provisional application No. 63/756,601, filed on Feb. 10, 2025.

(51) Int. Cl. G03F 7/00; G03F 7/20; G21K 1/06; H10P 76/20

(52) U.S. Cl. CPC G03F 7/70291; G03F 7/2004; G03F 7/70008; G03F 7/70825; G03F 7/70958; G21K 1/065; G21K 1/067; H10P 76/2047

(57) ABSTRACT

A maskless x-ray lithography system provided herein includes a source of an input x-ray beam having a wavelength between 1 nm and 20 nm, and employs an x-ray beam intensity modulator including a plurality of x-ray beam intensity modulator elements. Each x-ray beam intensity modulator element has an x-ray-reflective surface oriented with respect to the input x-ray beam at an x-ray beam grazing angle greater than zero degrees and no larger than an extinguishing grazing angle at which reflectivity is substantially zero for the input x-ray beam wavelength and x-ray-reflective surface material. This produces a plurality of modulated output x-ray beams each having an output intensity that is a fraction of the intensity of the input x-ray beam. A plurality of microlenses are provided, with each microlens oriented to focus a modulated output x-ray beam from the x-ray beam intensity modulator, to produce a plurality of focused, intensity-modulated x-ray beams.

### CROSS-REFERENCE TO RELATED APPLICATION

This application claims the benefit of U.S. Provisional Patent Application No. 63/756,601, filed Feb. 10, 2025, the entirety of which is hereby incorporated by reference.

### BACKGROUND

This invention relates to semiconductor microfabrication process technology, and more particularly relates to the fabrication of microscale and nanoscale structures, irrespective of the structures' specific industrial application.

In the fabrication of nanoscale structures with lateral dimensions at the microscopic level, so-called microstructures and nanostructures, such as features produced by semiconductor microfabrication processes, the substrate onto which a microstructure or nanostructures is to be produced is first coated with a radiation-sensitive film, called a “resist film.” The resist film is exposed to a pattern of radiation that changes the resist film's chemistry such that either the exposed portion or the unexposed portion of the resist film is removable by a process such as chemical processing. The pattern of the resist film remaining on the substrate surface after the processing can then serve to protect selected regions of the substrate from further processing, such as etching, ion implantation, material deposition, or other processes of alteration. This resist-film-based process, which is fundamental to the semiconductor microfabrication industry, as well as a wide range of other industries, is generally referred to as “lithography.” From its origin in Greek, the term “lithography” translates as “writing on stone.”

In general, in the current semiconductor industry, microfabrication of the most advanced semiconductor microchips utilizes so-called “EUV lithography,” in which the radiation employed to expose a resist film has a wavelength of about 13.5 nm. Although this wavelength has historically been considered in the soft x-ray range of radiation, the acronym EUV, which stands for “extreme ultraviolet,” has been applied and widely employed in the literature and in public. Conventional EUV lithography systems employ a series of mirrors to transfer the EUV radiation produced by a point-like, tin-based plasma source, toward a “photomask” which carries a pattern for which a resist film on a substrate surface is to be exposed.

Typically, each of the mirrors in the EUV system is composed of multiple alternating layers of molybdenum and silicon, each of sub-EUV wavelength thickness, thereby achieving, via constructive interference, much higher reflectivity than would be achieved with a single layer of material. Further in a conventional EUV lithography system, an additional series of multilayer mirrors is included to demagnify the image carried by the photomask, for example by a factor of 4, and direct the EUV radiation from the photomask to a resist film on the surface of a substrate, often a silicon substrate, whereupon the resist film is exposed to EUV radiation having the pattern image of the photomask. This EUV radiation exposure chemically modifies the resist film such that the resist film can then be chemically “developed,” revealing a demagnified relief image of the photomask. The relief image in the resist film can then be used for further processing as part of the microfabrication process for manufacturing integrated semiconductor circuits.

For many microfabrication processes, photomask-based EUV lithography is limiting due to high cost and complexity. A known method for maskless production of patterns in resist films with visible radiation is zone-plate-array lithography (ZPAL), as described in U.S. Pat. No. 5,900,637, entitled, “Maskless Lithography Using A Multiplexed Array of Fresnel Zone Plates,” issued May 4, 1999, and hereby incorporated by reference. ZPAL eliminates the need for both mirrors and photomasks as conventionally employed in EUV lithography. Instead, a ZPAL system employs microlenses, such as Fresnel zone plates, to focus radiation. In zone-plate-array lithography, a pattern to be created in a resist film on a substrate surface is first described in a software file, e.g., on a computer, and the described pattern is then formed in the resist by means of focal spots produced by an array of microlenses, which can be, but are not exclusively required to be, Fresnel zone plates.

Among the advantages of the use of Fresnel zone plates, or other diffractive-optical microlenses in ZPAL, is the ability to focus radiation wavelengths shorter than those in the ultraviolet regime. In particular, wavelengths in the soft x-ray regime, defined herein as including wavelengths between about 1 nm and about 20 nm, can be focused using microlenses such as Fresnel zone plates. This characteristic is particularly desirable because compared to the ultraviolet wavelength regime, the soft x-ray regime of shorter wavelengths enables relatively finer focal spots and hence higher resolution patterns to be exposable in resist films; as understood to those skilled in the art of lithography.

In order to achieve maximum efficacy in the production of patterns in a resist film with ZPAL it is important that the radiation intensity of each focal spot be adjustable. The radiation intensity of a focal spot and in general the radiation intensity of a given radiation beam, herein refers to the total power per unit area of the radiation that is perpendicular to the beam. That is, the number of photons of radiation passing through a given cross-sectional area over a given interval of time determines the intensity of the radiation at that area, and in the case of ZPAL, at a given focal spot.

In ZPAL, individual control and adjustment of the radiation intensity of each focal spot is critical for a range of considerations, predominantly to ensure that a uniform exposure dose of radiation is delivered across a resist film by an array of focal spots even if the individual zone plates are not identical, due, e.g., to fabrication tolerance, aberrations, or alignment error. The adjustment of radiation intensity, and corresponding radiation dose, at selected focal spots provides compensation for such variations. Individual focal spot control of radiation intensity also enables compensation for so-called lithographic proximity effects and other pattern-specific effects, as well as for resist film topography and variation. Individual control of the radiation intensity of each focal spot thereby is required in ZPAL to enable precise control of pattern linewidth and feature shape across a resist film.

There are known and commercially available radiation intensity modulator systems that are highly effective in modulating the radiation intensity of focal spots of visible-wavelength radiation, such as radiation wavelengths around 405 nm. Visible-wavelength radiation intensity modulators require normal-incidence reflection of input radiation, i.e., require input radiation to be directed perpendicularly to the modulator for reflection therefrom. Such an arrangement is not practical at soft x-ray wavelengths because normal incidence reflection of soft x-ray wavelengths renders the x-ray intensity too weak to be usable for lithography. Visible wavelength radiation intensity modulators that employ diffraction from gratings are likewise impractical at soft x-ray wavelengths because, for a given grating spatial period, the sine of the diffraction angle scales directly with wavelength. As a result, the angles required for diffraction at soft x-ray wavelengths are impractically small. As a result, maskless x-ray lithography with radiation intensity control of soft x-ray beams has heretofore been unachievable.

### SUMMARY

Herein is provided a maskless x-ray lithography system in conjunction with an x-ray beam intensity modulator provided herein that enables maskless x-ray lithographic methodology. In one embodiment, the maskless x-ray lithography system provided herein includes a source of an input x-ray beam having a wavelength between 1 nm and 20 nm. The system employs an x-ray beam intensity modulator, as provided herein, that includes a plurality of x-ray beam intensity modulator elements. Each x-ray beam intensity modulator element has an x-ray-reflective surface oriented with respect to the input x-ray beam at an x-ray beam grazing angle greater than zero degrees and no larger than an extinguishing grazing angle at which reflectivity is substantially zero for the input x-ray beam wavelength and x-ray-reflective surface material. This produces a plurality of modulated output x-ray beams each having an output intensity that is a fraction of the intensity of the input x-ray beam. A plurality of microlenses are provided with each microlens oriented to focus a modulated output x-ray beam from the x-ray beam intensity modulator. The plurality of microlenses together produce a plurality of focused, intensity-modulated x-ray beams to form a lithographic pattern.

In one embodiment, the maskless x-ray lithography system provided herein includes a source of an input x-ray beam having a wavelength between 1 nm and 20 nm. The system employs an x-ray beam intensity modulator, as provided herein, that includes a plurality of x-ray beam intensity modulator elements. Each x-ray beam intensity modulator element includes an x-ray-reflective surface having a vertically undulating surface profile with periodically spaced undulations along an extent of the x-ray-reflective surface. Portions of the periodically spaced undulations are oriented with respect to the input x-ray beam at an x-ray beam grazing angle greater than zero degrees and no larger than an extinguishing grazing angle at which reflectivity is substantially zero for the input x-ray beam wavelength and x-ray-reflective surface material. This produces modulated output x-ray beams including either a plurality of zero-order x-ray diffraction beams and/or a plurality of non-zero order x-ray diffraction beams. Each modulated output x-ray beam has an output intensity that is a fraction of input intensity of the input x-ray beam.

In a method for maskless x-ray lithographic patterning of a surface, an input x-ray beam having a wavelength centered at 13.5 nm is directed toward a plurality of separated molybdenum surfaces. Each molybdenum surface is oriented with respect to the input x-ray beam at an x-ray beam grazing angle greater than zero degrees and no larger than an extinguishing angle of 27 degrees, at which reflectivity is substantially zero for the input x-ray beam wavelength. This produces a plurality of modulated output x-ray beams each having an output intensity that is a fraction of the intensity of the input x-ray beam. The plurality of modulated output x-ray beams is directed to a plurality of microlenses oriented to focus the modulated output x-ray beams onto a surface in a lithographic pattern of intensity-modulated x-ray beams, for forming a lithographic pattern on the surface.

In a further method for maskless x-ray lithographic patterning of a surface, an input x-ray beam having a wavelength centered at 4.5 nm is directed toward a plurality of separated uranium surfaces. Each uranium surface is oriented with respect to the input x-ray beam at an x-ray beam grazing angle greater than zero degrees and no larger than an extinguishing angle of 13 degrees, at which reflectivity is substantially zero for the input x-ray beam wavelength. This produces a plurality of modulated output x-ray beams each having an output intensity that is a fraction of the intensity of the input x-ray beam. The plurality of modulated output x-ray beams is directed to a plurality of microlenses oriented to focus the modulated output x-ray beams onto a surface in a lithographic pattern of intensity-modulated x-ray beams, for forming a lithographic pattern on the surface.

With the x-ray beam intensity modulator provided herein, maskless x-ray lithographic systems are enabled for achieving lithography in the soft x-ray regime.

Other features and advantages will be evident from the description below and accompanying figures, and from the claims.

### BRIEF DESCRIPTION OF THE DRAWINGS

FIG. 1 is a schematic diagram of a maskless x-ray lithography system provided herein and including an x-ray beam modulator provided herein;

FIG. 2 is a schematic of an x-ray beam incident on the surface of a material for defining the grazing angle and angle of incidence of the x-ray beam;

FIG. 3 plots the reflectivity of a 4.5 nm-wavelength x-ray beam off of a surface of uranium as a function of x-ray beam grazing angle and plots the reflectivity of a 13.5 nm-wavelength x-ray beam off of a surface of molybdenum as a function of x-ray beam grazing angle;

FIGS. 4A and 4B are schematic views of an x-ray reflective surface showing the geometry of the interaction of an input x-ray beam and an output x-ray beam with the reflective surface;

FIGS. 5A and 5B are plan and cross-sectional schematic views, respectively, of an x-ray beam modulator element provided herein;

FIG. 6 is a schematic plan view of an array of modulator elements provided herein;

FIG. 7 is a schematic plan view of an array of modulator elements provided herein each modulator element embodying a suspended doubly supported beam including an x-ray reflective surface;

FIG. 8 is a schematic plan view of an array of modulator element actuators provided herein and positioned to actuate the modulator array of FIG. 7;

FIGS. 9A and 9B are plan and cross-sectional schematic views, respectively of a row of modulator elements in the modulator element array of FIG. 7 provided herein;

FIG. 10 is a schematic side view of a modulator element in the modulator element array of FIG. 7 provided herein in an actuated position;

FIGS. 11A, 11B, and 11C are schematic side views of a modulator element provided herein for diffraction of an input x-ray beam;

FIG. 12 is a schematic side view of two modulator element arrays provided herein, arranged in tandem and providing a multiplicity of beamlets as output;

FIGS. 13A and 13B are schematic side views of a cantilever beam modulator element and a compound modulator element including two cantilever beam modulator elements, respectively, provided herein;

FIG. 14 is a geometric construction of input x-ray beams and corresponding output x-ray beams for three different cantilever positions in the compound modulator element of FIG. 13B; and

FIG. 15 is a schematic side view of a compound modulator element including two doubly supported bridge modulator elements.

### DETAILED DESCRIPTION

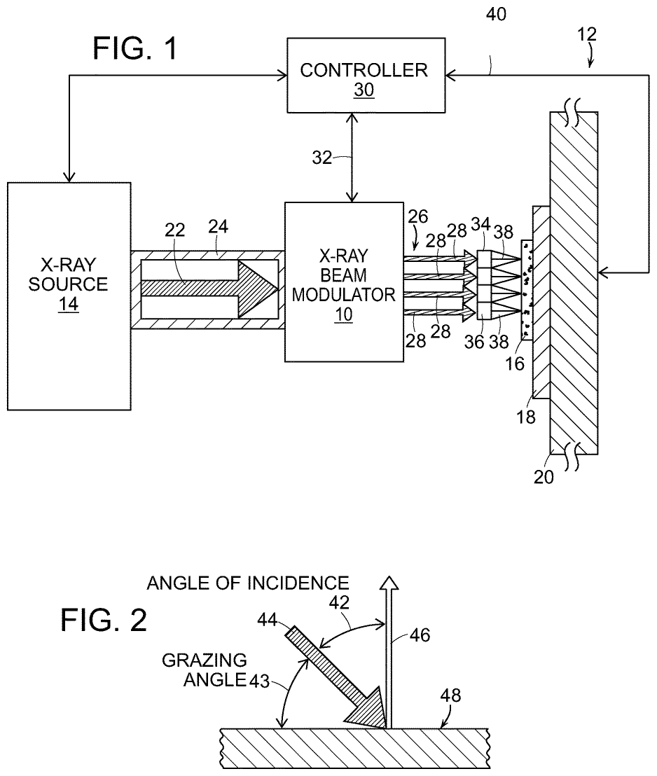

FIG. 1 is a schematic diagram of the x-ray beam radiation intensity modulator 10 provided herein, as configured for operation in and/or in conjunction with a maskless x-ray lithography system 12. The x-ray lithography system 12 includes, or is connected to accept an output from, a source 14 of radiation having a wavelength in the soft x-ray regime defined herein as a range of wavelengths that is between about 1 nm and about 20 nm. As explained in detail below, the x-rays provided by the x-ray source 14 are controlled by the x-ray beam radiation intensity modulator 10, hereinafter “x-ray beam modulator,” for lithographically producing a selected pattern in a lithographic resist film 16. The resist film 16 is disposed on the surface of a substrate 18, and the substrate 18 is supported on a positioning stage 20.

In one embodiment, the x-ray source provides an x-ray beam 22 directed to exit the source 14, through a containment chamber 24, such as an evacuated tube. The containment chamber 24 provides a path of delivery for directing the x-ray beam 22 to an input of the x-ray beam modulator 10. In general, the x-ray beam modulator 10 includes one or more modulator elements that interact with an input x-ray beam 22 and that produce an x-ray beam modulator output 26 including at least one modulated x-ray beam and preferably a plurality of modulated x-ray beams 28.

Each output modulated x-ray beam 28 is characterized by a separate radiation intensity that results from the processing of the input x-ray beam 22 by the x-ray beam modulator 10. A controller 30 communicates 32 with the x-ray beam modulator 10 to produce the modulated x-ray beams 28 by control of the x-ray beam modulator elements.

The modulated x-ray beams 28 at the output 26 of the x-ray modulator 10 are directed to a plurality of microlenses such as a microlens array. In one embodiment, the array of microlenses includes one microlens 36 for each modulated x-ray beam 28. In general, each microlens 36 focuses a modulated x-ray beam 28 into a focused x-ray beam 38. The focus of each focused x-ray beam 38 is a spot on the resist film 16. The controller 30 communicates 40 with the positioning stage 20 to control the position of the resist film 16 relative to the focused x-ray beams 38 by adjustment of the coordinates of the positioning stage 20. With this arrangement of components, the maskless x-ray lithography system 12 enables precise, reproducible, high-resolution maskless lithography in the soft x-ray wavelength regime. Embodiments of components are provided in detail herein below.

In one embodiment, the x-ray beam modulator 10 provided herein includes modulator elements for processing radiation in the soft x-ray regime, at wavelengths that are between about 1 nm and 20 nm, including at wavelengths of 4.5 nm and 13.5 nm. Generally, wavelengths shorter than about 1 nm penetrate readily through resist films and deposit insufficient energy in the film to be effective for lithography, but can be employed in applications herein for lithographic resist materials that accommodate the relatively low absorption at those wavelengths.

Conversely, wavelengths longer than about 20 nm are so strongly absorbed in resist films that the film must be impractically thin for subsequent application in etching and other processing steps. For the maskless lithography systems and methods provided herein, the preferred range of soft x-rays is between about 1 nm and 20 nm, and more preferably between about 3 nm and about 15 nm, with 4.5 nm and 13.5 nm being especially preferred.

The inventors herein recognized that modulation of x-ray beam radiation intensity can be achieved by exploiting a unique property of x-rays, namely that at x-ray wavelengths, including radiation wavelengths between about 1 nm and about 20 nm, the index of refraction of materials is less than unity. As used herein, the “index of refraction” of a material refers to the conventional index of refraction (n), a dimensionless number equal to the ratio of the radiation wavelength in vacuum to the radiation wavelength in the material. The extent to which the index of refraction of a material is less than unity depends on the atomic number and density of the material. For example, at the 4.5 nm x-ray wavelength, the index of refraction, n, of diamond is 0.9977, whereas the index of refraction, n, of uranium, having the highest atomic number of any naturally occurring material, is 0.9840. At the 13.5 nm x-ray wavelength, the index of refraction, n, of diamond is 0.9387 and the index of refraction, n, of molybdenum is 0.924.

The fact that an x-ray wavelength is longer in a material than in vacuum gives rise to a phenomenon unique to the x-ray regime, called “total external reflection,” (TER). Here, the term “total” implies only that the incident beam does not propagate into the material and instead reflects from the surface of the material. Some attenuation of beam intensity occurs, but propagation into the material does not occur. This can be understood by considering a related phenomenon but one that is in the visible range of radiation wavelengths; when a visible light beam transits from glass, where the index of refraction (n) is significantly larger than unity, into air, where the refractive index is very close to unity, the phenomenon of total internal reflection (TIR) occurs when the angle of incidence within the glass is larger than a characteristic, critical angle. This visible light phenomenon is also widely observed at the interface between water and air.

Total external reflection of x-rays occurs at a material surface when the angle at which the x-rays impinge the material surface is at a grazing angle that is no more than a critical angle, which is characteristic of a given material. Referring to FIG. 2, the angle of incidence 42 is defined as the angle between an incident beam 44 and the surface normal 46 with a material surface 48. The grazing angle 43 is defined as 90 degrees minus the angle of incidence. The requisite range of grazing angles below a critical angle for total external reflection can be modeled, calculated, and/or experimentally measured.

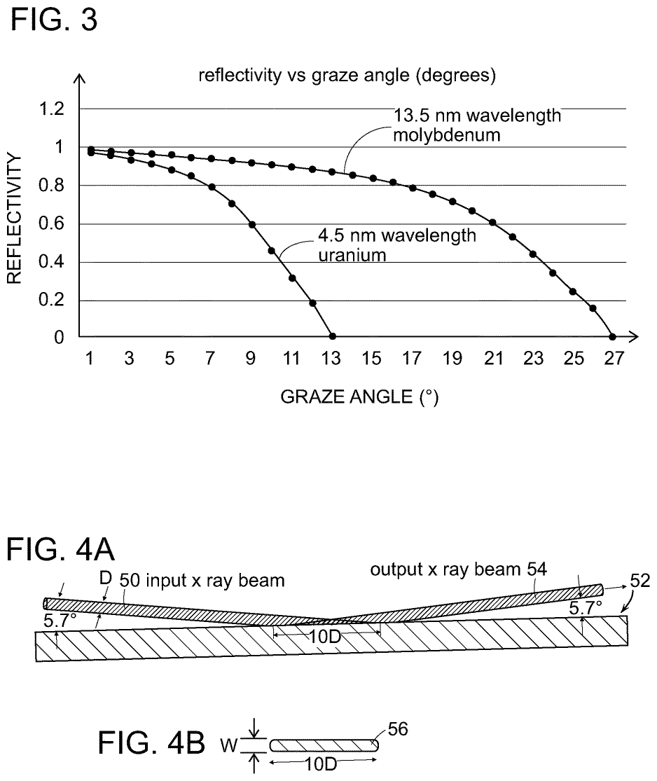

FIG. 3 shows plots of the calculated reflectivity of soft x-rays at two different wavelengths, 4.5 nm and 13.5 nm, each incident on surfaces of uranium and molybdenum, respectively, as a function of the angle of incidence of the x-ray beam on the surface of the respective material. The plotted reflectivity is determined for a uranium film of 10 nm in thickness residing on a 1000 nm-thick substrate of silicon nitride, and a molybdenum film of 20 nm in thickness residing on a 1000 nm-thick substrate of silicon nitride.

The plots of FIG. 3 show that in the case of uranium and an x-ray beam of 4.5 nm wavelength incident on the uranium surface, the reflectivity of the x-ray beam off of the uranium surface is a maximum at a grazing angle close to zero degrees and drops sharply for grazing angles larger than about 10 degrees. The reflectivity of the 4.5 nm-wavelength x-ray beam is effectively extinguished at about 13 degrees. At grazing angles larger than 13 degrees, the reflectivity of the 4.5 nm-wavelength x-ray beam off of the uranium surface is zero. In the case of molybdenum and an x-ray beam of 13.5 nm wavelength incident on the molybdenum surface, the reflectivity of the x-ray beam off of the molybdenum surface is a maximum at a grazing angle close to zero degrees and drops sharply for grazing angles larger than about 20 degrees. The reflectivity of the 13.5 nm-wavelength beam is effectively extinguished at about 27 degrees. At grazing angles larger than 27 degrees, the reflectivity of the 13.5 nm-wavelength x-ray beam off of the molybdenum surface is zero.

The term “extinguishing grazing angle” is herein given as that grazing angle at which the reflectivity of an x-ray-reflective surface goes to zero for a given x-ray-reflective surface material. Herein the term “critical angle” refers to that grazing angle, for a given x-ray beam wavelength incident on a given material, for which the cosine of the angle is equal to the index of refraction of the given material. For example, given a 4.5 nm x-ray beam wavelength incident on a surface of uranium, the critical angle is a grazing angle of about 10.3 degrees, agreeing with the plot of FIG. 3. Given a 13.5 nm x-ray beam wavelength incident on a surface of molybdenum, the critical angle is a grazing angle of about 22.5 degrees.

The inventors herein discovered that by adjusting the reflectivity of an x-ray beam from a material surface, the fractional power, or radiation intensity, of the reflected x-ray beam can be controllably varied, and can be varied across a plurality of reflected x-ray beam intensity values between about zero, at the extinguishing grazing angle, and a reflected x-ray intensity of over 95% of the input x-ray beam intensity, at a grazing angle close to zero degrees. Thereby, as provided herein, the radiation intensity of an x-ray beam is varied, or modulated, by controlling the reflectivity of the x-ray beam at a material surface across a range of possible modulation intensities that are in embodiments herein a quasi-continuous range of a plurality of modulation intensities. This reflectivity control is achieved herein by controlling the angle of incidence of an x-ray beam at a material surface. Based on this relationship, in the control method provided herein, a preselected output x-ray beam intensity is produced by means of a corresponding x-ray beam reflectivity resulting from a preselected input x-ray beam grazing angle with an x-ray-reflective material.

With this control methodology, then in embodiments herein, given a 4.5 nm-wavelength x-ray beam the intensity of which is to be modulated, the x-ray beam is directed to the surface of a layer of uranium, and the grazing angle that the x-ray beam makes with the uranium surface is controlled to be greater than about zero degrees, at which the reflectivity is maximized, and about 13 degrees, at which the reflectivity is substantially zero; correspondingly, the incident angle that the 4.5 nm x-ray beam makes with the uranium surface is controlled to be between 90 degrees, at which the reflectivity is maximized, and about 77 degrees, where the reflectivity is substantially zero. By controllably varying the grazing angle of an input 4.5 nm-wavelength x-ray beam between an angle near to zero degrees and about 13 degrees with a uranium surface, there is produced an output x-ray beam at 4.5 nm having an intensity that is modulated to any fraction of the input x-ray beam intensity between almost about 100%, at close-to-zero-degree grazing angles, and 0%, at the extinguishing grazing angle of about 13 degrees. In general, herein, for any x-ray beam wavelength and any x-ray-reflective surface material, the term “fraction” as applied to an output x-ray beam intensity relative to an input x-ray beam intensity is to be understood to include 0% and any value between 0% and 100%.

In embodiments herein, given a 13.5 nm-wavelength x-ray beam the intensity of which is to be modulated, the x-ray beam is directed to the surface of a layer of molybdenum and the grazing angle that the x-ray beam makes with the molybdenum surface is controlled to be a small angle close to zero degrees, for maximum reflectivity, and 27 degrees, at which the reflectivity is substantially zero; correspondingly, the incident angle that the 13.5 nm-wavelength x-ray beam makes with the molybdenum surface is controlled to be between about 90 degrees, at which the reflectivity is maximized, and 63 degrees, where the reflectivity is substantially zero. By controllably varying the grazing angle of an input 13.5 nm-wavelength x-ray beam between an angle close to zero degrees and about 27 degrees with a molybdenum surface, there is produced an output x-ray beam at 13.5 nm having an intensity that is modulated to any fraction of the input x-ray beam intensity between almost about 100%, at close-to-zero-degree grazing angles, and 0%, at the extinguishing grazing angle of about 27 degrees.

The x-ray beam intensity modulator provided herein thereby changes, or modulates, the intensity of an input x-ray beam to produce an output x-ray beam intensity that can be different from the input x-ray beam intensity and that can range in intensity value across a range of different intensity values that are fractions of the input x-ray beam intensity, corresponding to input grazing angles up to the extinguishing grazing angle at which reflectivity is substantially zero. The modulator thereby reflects some fraction of an input x-ray beam, between zero and about 100%, as an output x-ray beam, and either absorbs the remaining fraction of the input x-ray beam or discards a portion of the input x-ray beam via diffraction.

The radiation intensity of an x-ray beam herein refers to the total power per unit area of the x-ray beam radiation that is perpendicular to the x-ray beam. The number of photons, i.e., the quantity of x-rays, and the energy, or frequency, of each individual x-ray photon, sets the intensity of an x-ray beam. The power of the x-ray beam represents the total energy of the beam that is delivered per unit time, in watts (W), so the intensity of the x-ray beam is the energy of the x-ray beam that is delivered per unit time per unit area, in W/m². That is, the number of photons of x-ray radiation passing through a given cross-sectional area over a given interval of time determines the intensity of the x-ray beam at that area. In the modulation method provided herein, the number of x-ray photons that are reflected from a surface of a material is controlled by controlling the grazing angle at which the photons impinge the surface, resulting in control of the intensity of a reflected x-ray beam.

This reflectivity control is enabled by the x-ray beam modulator provided herein with one or more intensity modulator elements. Each modulator element embodies one or more regions, structures, forms, layers, or other arrangement of at least one x-ray-reflective material. The angle, or orientation, of the surface of the x-ray-reflective material is controlled with respect to an input x-ray beam that is directed to the surface of the x-ray-reflective material. Specifically, the angular orientation of the x-ray-reflective surface with respect to the input x-ray beam is spatially controlled to produce a grazing angle of greater than about zero degrees and the x-ray beam extinguishing grazing angle that yields zero reflectivity for the reflective surface. The modulator element is thereby controlled to achieve a selected x-ray beam reflectance and produce a reflected output x-ray beam having a correspondingly modulated intensity.

The geometry and arrangement of each modulator element preferably meets criteria for enabling interaction of an input x-ray beam with the x-ray-reflective material of the modulator element and generation therefrom of an output x-ray beam. Referring to FIG. 4a, there is shown a collimated input x-ray beam 50, of diameter, D, incident on the surface 52 of a reflecting material at a grazing angle of 5.71 degrees, which corresponds to an angle of incidence of 84.29 degrees. An output x-ray beam 54 of the same diameter, D, is reflected from the surface 52, at the matching grazing angle of 5.71 degrees. In accordance with optical geometric construction, it is found that the lateral extent, L, of the surface 52 across which the input x-ray beam 50 impinges, and the output x-ray beam 54 reflects, is given by the beam diameter D divided by the sine of the grazing angle, here 5.71 degrees, resulting in a factor of ten times the beam diameter, given as 10·D.

Based on the width and lateral extent of the surface region that gives rise to the output x-ray beam, the inventors herein discovered that for a collimated input x-ray beam, incident on an x-ray-reflective surface at a given grazing angle, the diameter of the corresponding output x-ray beam is approximately equal to the width of the x-ray-reflective region of the surface, provided that the input x-ray beam is at least as wide as the x-ray-reflective region, and provided that the length of the x-ray-reflective region is equal to the region width divided by the sine of the grazing angle. In embodiments herein, the width and length of an x-ray-reflective region of a surface are selected with this geometric arrangement to control the diameter of an output x-ray beam for an input x-ray beam diameter that is at least as wide as the x-ray-reflective region. This is a minimum input x-ray beam diameter; the input x-ray beam diameter can be much broader in embodiments herein. This recognition provides criteria for the design of the elements of the x-ray beam modulator.

As indicated in FIG. 1, although the input x-ray beam 22 is broad, the x-ray beam modulator 10 produces an output 26 of a multiplicity of output beams 28.

Each output beam 28 is directed to an array 34 of microlenses 36. Each output beam 28 preferably has a beam diameter that is equal to, or slightly larger than, the diameter of the microlens to which it is directed, while not overlapping with any nearby microlens. The diameter of each microlens is generally between about 10 micrometers and 100 micrometers. Thus, in preferred embodiments, the x-ray beam modulator produces a multiplicity of output x-ray beams that are controlled in both intensity and diameter. The inventors herein discovered that for a given broad input x-ray beam 22 that is collimated, the diameters of each of the output x-ray beams 28 can be determined by the dimensions of x-ray-reflective regions of the modulator elements.

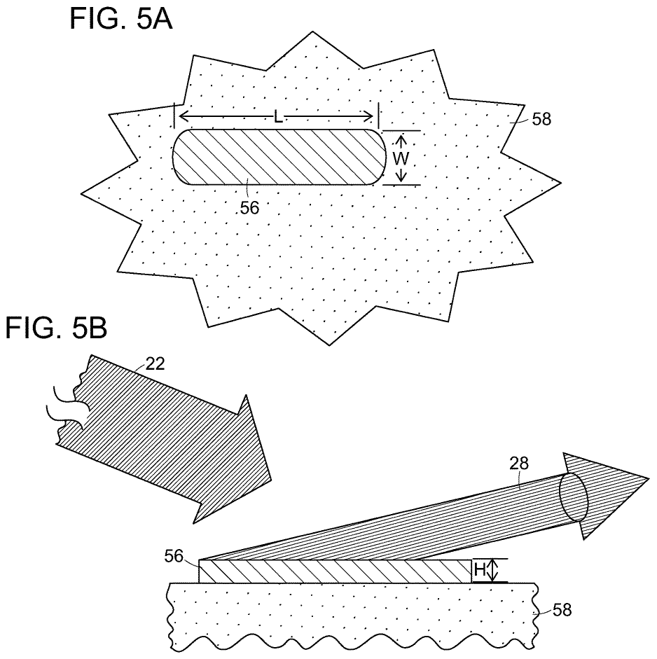

In one embodiment, referring to FIGS. 5A-5B, an x-ray beam modulator element 56 includes a region of x-ray-reflective material disposed on an underlying substrate 58. The modulator element 56 has a length, L, a width, W, and as shown in FIG. 5B, the modulator element 56 is characterized by height, H. An input x-ray beam 22, such as a collimated, broad-area x-ray beam, is directed to the modulator element 56, causing the input x-ray beam to impinge the surface of the element 56 at a selected grazing angle that is greater than zero and less than the extinguishing grazing angle, characteristic of the material, at which zero reflectivity occurs at the x-ray beam wavelength.

In a non-limiting example of a modulator element embodiment, the modulator element 56 of FIG. 5B is provided as a region of highly reflective x-ray-reflecting material, such as uranium (U) in the case of radiation of 4.5 nm wavelength, or molybdenum (Mo) in the case of radiation of 13.5 nm wavelength, and the input x-ray beam is directed to the surface of the highly reflecting region at an angle of 5.7 degrees with the horizontal. At this grazing angle, for both U and Mo at the corresponding x-ray wavelengths, strong x-ray reflection, generally greater than 90%, occurs, as indicated by the plots in FIG. 3. This high degree of reflection, in conjunction with the properly designed length and width of the U or Mo x-ray-reflective region, causes the reflected x-ray beam 28 to become circular, as indicated in FIG. 5B.

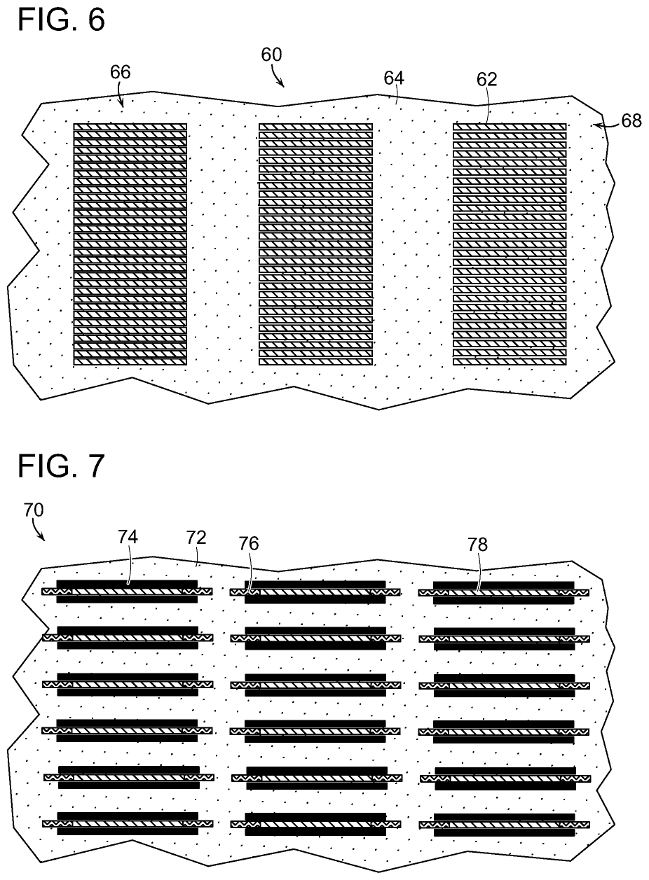

Referring to FIG. 6, in one embodiment, there is provided an array 60 of modulator elements 62. The modulator elements 62 are each disposed on or over a substrate 64, and can be arranged, e.g., as a rectangular array of columns 66 and rows 68 of modulator elements. The modulator array is configured in any suitable arrangement for interaction with an input x-ray beam. In one embodiment herein, the x-ray beam modulator includes at least one modulator element. In further embodiments, the x-ray beam modulator includes a plurality of modulator elements, e.g., between about 9 and about 1 million. In other embodiments, the x-ray beam modulator includes an array of modulator elements having a number of rows between about 3 and about 1000, and a number of columns between about 3 and about 1000.

In embodiments herein, one or more modulator elements of the x-ray beam modulator are structurally moveable and are controlled to take on a range of structural positions to impose an orientation for a selected input x-ray beam grazing angle with the modulator elements in the manner explained above. This structural moveability enables a modulator element to have a range of different grazing angular orientations with respect to an input x-ray beam, between close to zero degrees grazing angle and no more than the extinguishing grazing angle, thereby enabling control of the degree of reflection of an x-ray beam off of the surface of a modulator element and corresponding control of the intensity of the output x-ray beam reflected off of the surface of the modulator element. Referring to FIG. 7, in one embodiment of such, there is provided an array 70 of modulator elements that are each structurally moveable and free to change position. In this configuration, a suitable support structure 72, such as a substrate, a base, a support, a foundation, or an understructure, is provided with an array of indentations 74, such as cavities, trenches, slots, channels, pits, or other suitable geometry, extending to a selected depth therein. Extending over and suspended across each indentation is one or more material regions forming at least one modulator element. In the plan view of FIG. 7, there is shown an embodiment in which a first suspended region 76 extends across each indentation 74, and a second, top suspended region 78 extends for at least a portion of the first suspended region 76, atop the first suspended region 76. The second suspended region 78 is formed of a material selected for reflection of an incoming x-ray beam off of the surface of the material, and is fully exposed.

In embodiments herein, the materials that are suspended over an indentation 74 are sufficiently mechanically flexible to be vertically moveable in a direction perpendicular to the plane of the support substrate 72 by at least about 5 nanometers. For some embodiments, it is preferred to include two or more layers of suspended regions in a modulator element; FIG. 7 is an example of two layers of suspended region material. Two or more layers of material can be preferred particularly for embodiments in which the material selected for reflection of an incoming x-ray beam is so thin that a mechanically supporting material layer is required under the top reflector material. In other embodiments, the material of at least one region suspended over an indentation 74 has a characteristic that enables the material to be actuated for vertical movement. Such vertical actuation is imposed in embodiments herein by electrostatic, magnetostatic, piezoelectric, differential thermal expansion or contraction actuation mechanism, or other suitable actuation mechanism. Referring back to FIG. 1, the controller 30 controls the actuation of the modulator element position, e.g., with electronic control.

Considering the material of the modulator element to be employed for reflection of an x-ray beam, the material is selected based on the characteristic reflective properties of the material for a selected x-ray wavelength. The reflective properties are determined by the material's refractive index, which is wavelength dependent. In the two exemplary, but not limiting, embodiments illustrated via FIG. 3, uranium (U) is the preferred modulator material for modulating the intensity of x-rays having a wavelength of about 4.5 nm. At an x-ray wavelength of 4.5 nm, uranium provides an index of refraction n=0.984, with the largest difference from a refractive index of unity (1), and very lower absorption. As a result, uranium provides the highest reflectivity of 4.5 nm-wavelength x-rays. In another example, at an x-ray wavelength of 4.5 nm cobalt has an index of refraction of 0.986, which is a smaller difference from unity compared to uranium, and has an absorption value that is three times that of uranium. In another example, at an x-ray wavelength of 4.5 nm gold has an index of refraction of 0.899, which is a larger difference from unity compared to uranium, but gold has an absorption value that is eight times that of uranium.

Therefore, the reflectance of gold is not as high as that of uranium at an x-ray wavelength of 4.5 nm. Uranium is therefore a most preferred x-ray-reflective material for modulation of 4.5 nm-wavelength x-rays.

In the second exemplary embodiment illustrated via FIG. 3, molybdenum (Mo) is the preferred modulator material for modulating the intensity of x-rays having a wavelength of about 13.5 nm. At an x-ray wavelength of 13.5 nm, molybdenum provides an index of refraction n=0.924, with the largest difference from a refractive index of unity (1), and a very low absorption. As a result, molybdenum provides the highest reflectivity of 13.5 nm-wavelength x-rays and is a most preferred x-ray-reflective material for modulation of 13.5 nm-wavelength x-rays.

For an x-ray beam having another wavelength in the soft x-ray range between about 1 nm and about 20 nm, the preferred modulator material has an index of refraction with the largest difference from unity (1) and the lowest attenuation, among known materials. As will be understood by those skilled in the art, tabulated values of index of refraction and tabulated values of x-ray absorption by materials at different wavelengths can be accessed. For x-ray beams having a wavelength of about 4.5 nm or 13.5 nm, U and Mo are, respectively, the preferred materials for embodiments including the modulator element 56 of FIG. 5A, and 5B, the modulator element regions 62 of FIG. 6, and the upper modulator element region 78 of FIG. 7.

It is recognized that uranium is chemically reactive and readily forms an oxide surface coating. Thus, in other embodiments herein, the reflective material is provided as a uranium alloy that is resistant to oxidation. Here, a uranium-nickel alloy, with the percentage of Ni ranging between about 9% and about 25%, can be employed. In other embodiments, one or more protective coatings are provided on the surface of a uranium modulator region to effectively preserve most of the desirable features of a uranium reflection surface while avoiding oxidation of the uranium surface. Here, in one embodiment, a carbon coating is disposed on a uranium surface to inhibit oxidation while not significantly altering the soft x-ray reflectivity. Herein, the terms uranium, uranium film, and uranium layer are to be understood to include layers of uranium alloys or uranium-containing compounds as well as layers of uranium coated with one or more protective layers. Turning back to the modulator arrangement of FIG. 7, in embodiments herein given, an upper, exposed modulator element layer 78 of uranium has a thickness of between about 10 nm and about 100 nm. In another embodiment a carbon coating layer of about 20 nm in thickness is disposed on top of the uranium surface.

For many x-ray-reflective materials, such as uranium and molybdenum, it is preferred, as shown in FIG. 7, to provide an underlying material layer or layers 76 extending across each indentation 74, under the reflective layer, as a physical support of the upper layer. The underlying material layer enables vertical actuation of the modulator element as well as physical support of the upper layer. The lower material layer 76 thereby operates as a suspended bridge carrying the upper layer 78. The lower material preferably is provided with a selected internal stress that enables flatness in the absence of physical deflection, and with a material composition that enables physical actuation. In one embodiment, a composition of silicon nitride is provided as the underlying material layer 76. For many applications, a silicon nitride underlying material is convenient because silicon nitride can be deposited on a conventional microfabrication substrate, such as silicon or glass, using widely available equipment. Moreover, the properties of silicon nitride films, such as internal stress, can be varied over a wide range, from compressive to tensile, by controlling the conditions of deposition. In one preferred embodiment of the modulator element, a uranium or molybdenum layer is disposed on a silicon nitride bridge layer extending across an indentation in a substrate. In other embodiments, a material other than silicon nitride, such as silicon dioxide, diamond, a diamond-like carbon composition, or other suitable material, is provided as a suspended supporting bridge layer under a reflective layer.

For some applications, diamond is a preferred suspended, supporting material because diamond has the highest thermal conductivity of any material. This characteristic is exploited in the modulator element herein to accommodate absorption of some fraction of the input x-ray beam intensity. As explained above, each modulator element absorbs a fraction of the input beam intensity that is not reflected. Therefore, the underlying material on which the selected reflection surface material is supported, is preferably a good thermal conductor, for thermally conducting the x-ray beam power that is absorbed by a modulator element. Diamond or other good thermally conducting material can therefore be preferred for the suspended supporting material.

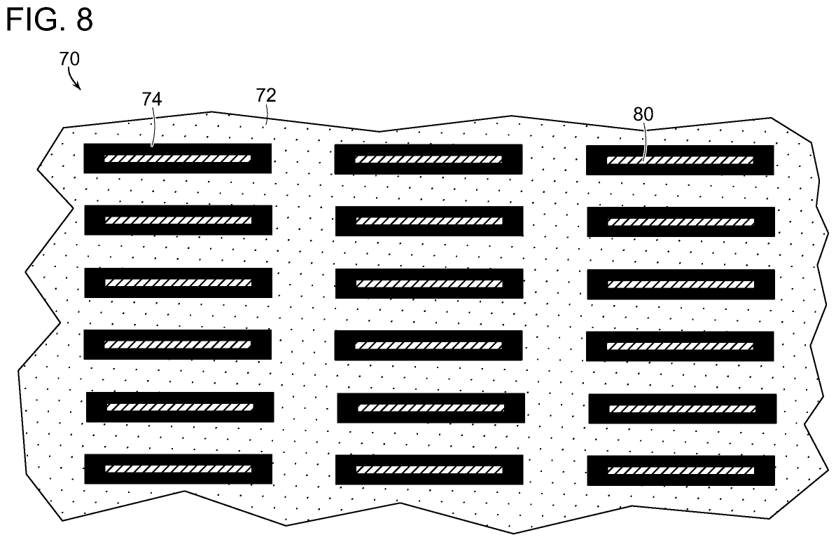

Given the suspended modulator element array of FIG. 7, for many applications an electrostatic actuation method is preferred for vertically actuating each modulator element. In embodiments herein electrostatic actuation is implemented with one or more electrically conducting electrodes sited at each modulator element. Referring to FIG. 8, in such an embodiment, the array 70 of modulator elements includes indentations 74 in a substrate 72, with an electrically conducting electrode 80 disposed on the floor of each indentation. The suspended modulator element layers are not shown in FIG. 8 for clarity. In embodiments herein, the electrode material is electrically conducting, and is implemented as, for example, silicon, polycrystalline silicon or a metal, such as aluminum. Because the indentations 74 are relatively large, measuring at least about 10 micrometers by about 10 micrometers, electrical contact to the electrodes are preferably made from the back side of the substrate 72 using methods well known in the semiconductor and MEMS industries. With this arrangement, each modulator element in the array is individually addressable and controllable to impose a selected x-ray beam reflectivity on each modulator element in the array of modulator elements. A controller, like the controller 30 shown in FIG. 1, and/or a controller internal to the modulator system 10, is here employed.

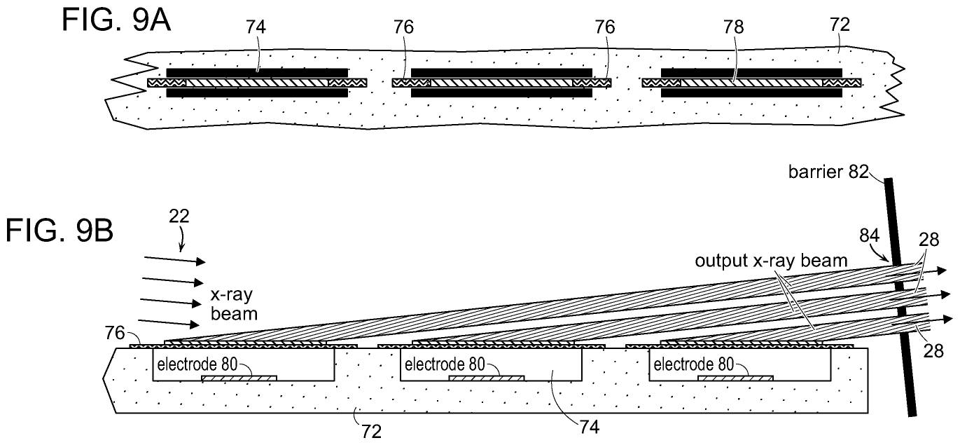

FIG. 9A is a plan view of one row of modulator elements in an array of suspended modulator elements that each include an electrode for electrostatic actuation thereof, with FIG. 9B showing in cross-section the electrode 80 in each indentation 74 for actuating each reflective modulator element material 78 suspended over the indentation 74. A broad-area input x-ray beam 22 directed at a grazing angle to the modulator elements, when in the substantially planar position of FIG. 9B, is converted into a plurality of output x-ray beams 28, one output x-ray beam 28 for each modulator element in the modulator element array having the requisite position for reflectance.

As shown in FIG. 9B, in embodiments herein there is included a barrier 82 having a wall disposed perpendicular to the direction of output x-ray beams 28 produced by the modulator. The wall of the barrier 82 includes apertures 84 sited along the wall to allow passage of the output x-ray beams 28 out of the modulator.

The apertures are therefore preferably sited to align with the direction of the output beams. The solid regions of the barrier wall 82, between the apertures 84, prevent stray and extraneous x-rays and other radiation from exiting the modulator. In embodiments herein, the barrier is provided as, e.g., a silicon nitride membrane of, e.g., about 1.1 micrometers in thickness, with appropriate holes etched therein to provide apertures. Such a membrane absorbs about 99 percent of x-rays incident on the membrane, at x-ray wavelengths of both 4.5 nm and 13.5 nm. With this arrangement, then as shown in FIG. 1, the x-ray beam modulator 10 produces a plurality of output x-ray beams 28, and unwanted stray radiation is prohibited from the output of the modulator 10.

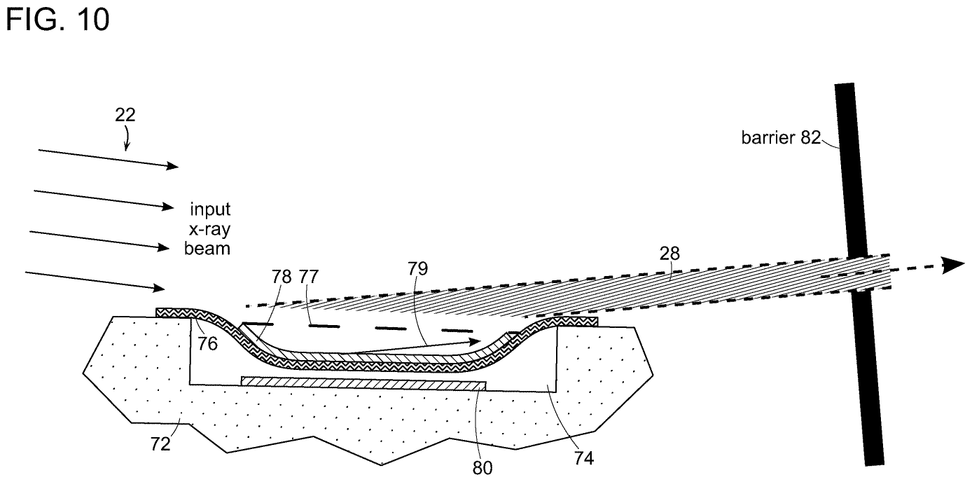

In electrostatic actuation of a selected modulator element in an array of modulator elements, referring to FIG. 10, the electrode 80 of a selected modulator element is addressed by applying a suitable electrical voltage, preferably of less than about 100 volts, to that electrode. With voltage application to the electrode 80, the materials 76, 78 suspended over the electrode deflect downward, toward the electrode. This deflection changes the grazing angle of incidence between the input x ray beam 22 and surface regions of the upper reflective material, thereby causing a change in the degree of x-ray reflection off of the material surface and the degree of x-ray absorption into the material. As shown in FIG. 10, when the materials 76, 78 are undeflected, shown by a dotted line 77, then the output x-ray beam 28 exits an aperture in the barrier 82. In one embodiment provided herein, when a portion of the deflected upper material layer is deflected to be oriented at an angle relative to the input beam corresponding to grazing incidence reflection, any such reflected radiation is obstructed from exiting the modulator, either by the sidewall of the indentation, as indicated by the arrow 79, or by the barrier wall 82. As a result, only selected x-ray beams exit the modulator. This configuration enables on/off modulation of the input x-ray beam.

In embodiments provided herein, the x-ray beam modulator element is arranged to modulate the intensity of an output x-ray beam in a quasi-continuous manner, across a range of different intensity values between a maximum output x-ray beam intensity and a minimum output x-ray beam intensity, including a substantially zero output x-ray beam intensity. In embodiments herein, the x-ray beam modulator includes one or more modulator elements each reflecting a selected fraction of an input x-ray beam intensity and either absorbing or discarding the remaining fraction of the input x-ray beam intensity, so that the intensity of the output x-ray beam includes only the reflected fraction of the input x-ray beam. As explained above, this is achieved by controlling the grazing angle of the input beam incident on the surface of the modulator elements.

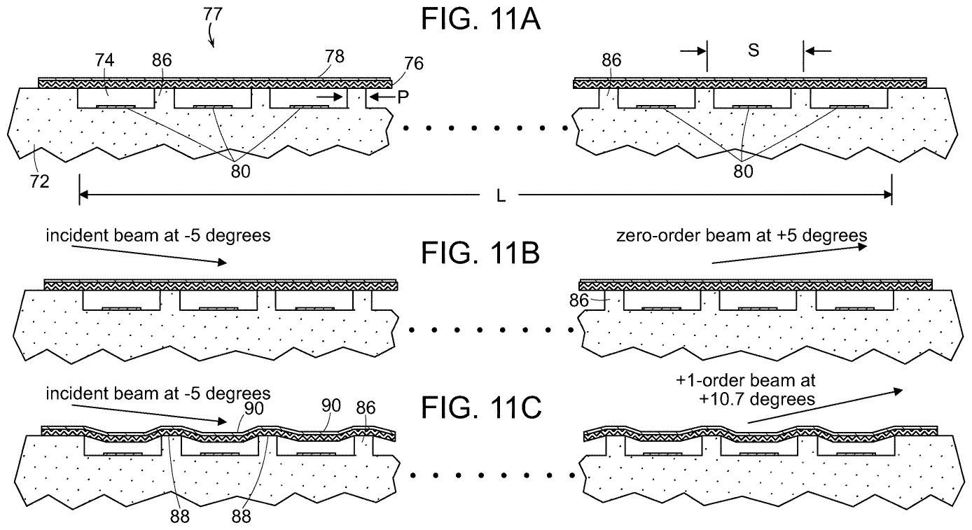

Referring to FIG. 11A, in one embodiment of such, the deflectable layers 76, 78, or other material configuration with an exposed x-ray-reflective surface of a modulator element 77, are disposed over an indentation 74 that includes a plurality of ridges, posts, columns, pillars, studs or other vertical structures 86 that are spaced across the indentation 74. In one embodiment, the vertical structures are embodied as walls between separated indentations, or other arrangement. The vertical structures 86, hereinafter termed ridges, are in embodiments herein arranged with the x-ray-reflective surface layer 78 and other layers sitting atop the ridges 86.

In one embodiment, the indentations or indentation 74 includes an actuator element or actuator elements, between the ridges 86, to actuate the orientation of material layers 76, 78. In one embodiment, one or more actuation electrodes 80 are sited in the indentations or indentation 74. In one embodiment, each ridge has an extent P and the ridges are spaced apart from each other with a spacing S across the length L of the modulator element 77. In one example, the upper reflective layer 78 is a Mo film of about 20 nm in thickness atop a support layer 76 of silicon nitride of about 1 micrometer in thickness. In another example, the upper reflective layer 78 is a U film of 10 nm in thickness atop a support layer 76 of silicon nitride of about 1 micrometer in thickness. The length L of the modulator element for these examples is about 230 micrometers, the extent P of each ridge 86 can be about 0.1 micrometers, and the spacing S of ridges can be about 1 micrometer.

Referring to FIG. 11B, given an embodiment of electrostatic actuation, but with no voltage applied to the electrodes 80, the deflectable layers 76, 78 are in a quiescent, substantially flat position that reflects grazing-angle input x-ray beams in the manner described above, producing output x-ray beams having some fraction of the intensity of the input x-ray beams. Referring to FIG. 11C, when a selected voltage is applied to the electrodes 80, the deflectable layers 76, 78 are pulled downward, toward the electrodes, due to electrostatic actuation. This downward deflection is not at the sites of the supporting ridges 86, resulting in a rippling, or undulation, of the vertical profile of the layers along the length L of the layers 76, 78.

Due to the undulating surface height of the reflective upper layer 78 of the modulator element 77, first portions 88 of the upper layer 78 are substantially parallel to the plane of the support structure 72, while second portions 90 of the upper layer 78 are likewise substantially parallel to the plane of the support structure 72 but are at a different height than the first portions 88. The first portions 88 are located around the peak of the undulation, at the site of ridges 86, while the second portions 90 are located around the minimum, or trough, of the undulation, at sites between the ridges 86. Both first and second portions 88 and 90 of the upper layer, have some region that is substantially parallel to the plane of the support structure, which gives rise to strong specular reflection of an input x-ray beam, while the sloped sections in between the first and second portions 88 and 90 of the upper layer give rise to absorption of the input x-ray beam if the input x-ray beam impinges thereon. In other words, some fraction of the surface area of the upper layer 78 is in a grazing angular orientation, relative to the input x-ray beam, that is greater than zero degrees and less than the extinguishing angle, thereby producing strong specular reflection of the input x-ray beam, while some fraction of the surface area of the upper layer 78 is in an angular orientation, relative to the input x-ray beam, that causes absorption of the input x-ray beam. The percentage of the upper layer surface that is reflective, being oriented with an input x-ray beam grazing angle greater than zero degrees and no more than the extinguishing grazing angle, relative to the percentage of the upper layer surface that is absorptive, in one embodiment herein determines the intensity of the output x-ray beam that is produced by the modulator 77.

If the ridges 86 of the modulator, as shown in FIGS. 11A-C, are spaced periodically, e.g., with spacing S, along the direction of trajectory of an input x-ray beam, then the periodic vertical undulation profile of the surface layers 76, 78, by application of a voltage to electrodes 80, gives rise to the phenomenon of diffraction. The resulting distinctly specular x-ray beams reflected from the parallel first and second portions 88 and 90 of the reflective surface are then referred to as zero-order beams. For example, given a periodic spacing S of the ridges 86 of 1 micrometer, and given an orientation of the element 77 so that input x-ray beam has a grazing angle of 5 degrees with the parallel portions 88 and 90 of the undulating surface, then the specular reflected 5 degree zero-order beams are accompanied by at least one non-specular diffracted beam. For example, for an input x-ray beam wavelength of 4.5 nm, a so-called +1-order diffracted beam emerges at an angle 2.4 degrees above the specular-reflection angle of 5 degrees, i.e., at an angle of 7.4 degrees above the horizontal plane depicted in FIGS. 11A-C. For an input x-ray beam wavelength of 13.5 nm, the +1 diffracted beam emerges at an angle 5.7 degrees above the specular-reflection angle of 5 degrees, i.e., 10.7 degrees above the horizontal plane depicted in FIGS. 11A-C. The ratio of output x-ray beam radiation in the zero-orders to soft x-ray beam radiation in the +1 orders is determined by the depth of deflection, or undulation profile, of the two modulator element beam layers 76, 78, which, in turn, is set by the magnitude of the voltage applied to the electrodes 80.

In embodiments herein for diffractive processing to produce modulated output x-ray beams in this manner, the first and second portions, 88, 90 of the undulating layers 76, 78, are oriented with respect to an input x-ray beam at a grazing angle greater than zero and no more than the extinguishing grazing angle for the input x-ray beam wavelength and the material of the x-ray-reflective surface, in the manner previously described. Referring again to FIG. 11C, as explained above, there are first and second portions 88 and 90 of the vertically undulating profile of the upper layer 78 that are substantially parallel to each other. These portions 88, 90 are oriented with respect to an input x-ray beam at an x-ray beam grazing angle greater than zero degrees and no larger than an extinguishing grazing angle at which reflectivity is substantially zero for the input x-ray beam wavelength and x-ray-reflective surface material.

Continuing with an example of 1 micrometer periodicity of spacing, S, for the array of ridges 86 in FIGS. 11A-C, and given embodiments herein in which the ridge widths are less than about 1 micrometer and preferably a small fraction of 1 micrometer, for example between about 0.1 micrometer and 0.2 micrometer, then deflection of the deflectable modulator element beam layers 76, 78 yields a prescription for first and second portions 88 and 90 that are substantially equal in length, over a certain range of deflection distance. The zero-order x-ray beam that reflects from first portions 88 and the zero-order x-ray beam that reflects from second portions 90 then emerge from the modulator element at the same angle, equal to the incident x-ray beam grazing angle, which is less than the extinguishing grazing angle, but with different path lengths, and hence can interfere with each other. For a ridge spacing periodicity S of 1 micrometer, maximum destructive interference in the zero-order x-ray beam, and hence minimum zero-order intensity, occurs at a deflection distance, or undulation profile depth, of the layers 76, 78 of about 13 nm for an x-ray beam of 4.5 nm in wavelength, and the minimum zero-order intensity occurs at a deflection distance, or undulation profile depth, of about 39 nm for an x-ray beam of 13.5 nm in wavelength. If the deflection distance for minimum zero-order intensity also corresponds to a deflection distance for which the first and second portions 88 and 90 have substantially the same length, then the zero-order intensity is substantially zero.

It is noted that the fraction of an x-ray beam intensity removed from a zero-order beam can appear in one of the other diffracted beams, including the +1 beam. Thus, although FIGS. 11A-C and the subsequent description refer to the zero-order beam as an output x-ray beam 28, in other embodiments herein a different diffracted beam, for example the +1 diffracted beam, is employed as an output x-ray beam 28 in FIG. 1. In this case, the quiescent state, i.e., with no voltage applied to the electrodes 80, the deflectable material layers 76, 78 are substantially flat and the intensity of the +1 beam is substantially zero. Conversely, when the deflectable layers 76,78 are deflected to a depth that minimizes the zero order, the +1 order is significantly enlarged.

This diffraction-based modulation is most effective when the number of ridges 86 of a modulator element, and hence the number of undulations that can be controllably formed along the length of the modulator element, is greater than about 5. For example, given an output x-ray beam of 20 micrometers diameter exiting the modulator element at an angle of 5 degrees above the plane of the element, then geometrically, the length of the modulator element is preferably at least 20 micrometers divided by sine of the exit angle, here 5 degrees, prescribing a modulator element length of about 229 micrometers. Accordingly, with the ridges 86 spaced apart with a period of 1 micrometer, then the diffraction-based modulator element preferably includes 229 or more ridges.

With this arrangement, the application of selected voltages to the modulator element electrodes 80 enables the modulator element to produce an output x-ray beam having an intensity at substantially any value between a corresponding maximum value and substantially zero. Because to a first approximation the extent of deflection, i.e., undulation profile, of the layers 76, 78 is proportional to the voltage applied to the electrodes, the modulation intensity range is as continuous as the voltage value range; and thus there is a substantially continuous range of output x-ray beam intensity. The voltage range corresponding to the range of x-ray intensity modulation is dependent on the stiffness of the material layers 76, 78 and is preferably determined experimentally for a selected modulator structure and material combination for a selected input x-ray beam wavelength. With calibration from experimental measurement, modulator control is imposed with preselected voltage levels specified for corresponding preselected x-ray beam intensity modulation.

In embodiments herein, the x-ray beam modulator includes modulator elements that enable the modulator to impose both on/off x-ray beam intensity modulation and quasi-continuous, variable-intensity x-ray beam modulation.

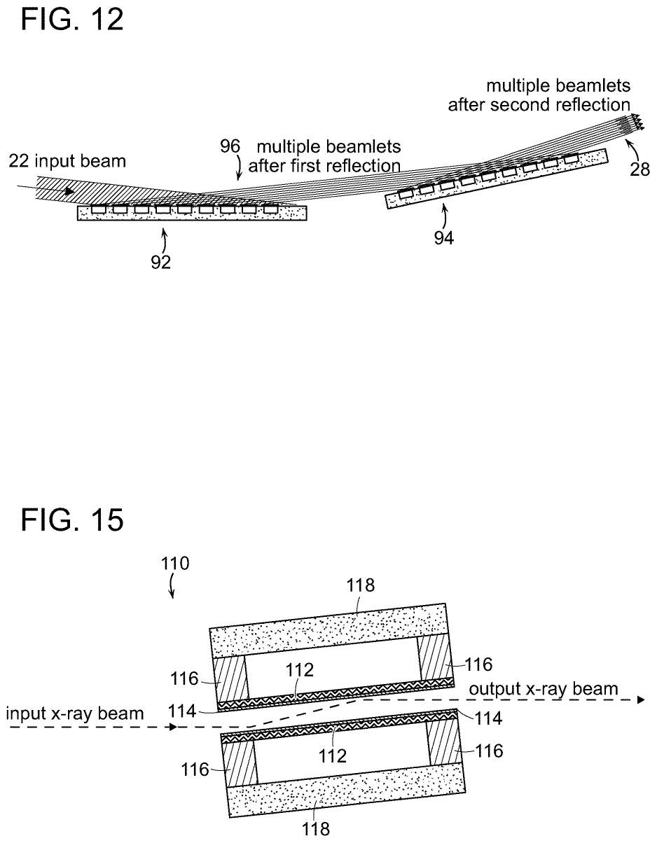

Referring to FIG. 12, in one example of such, there are included in the x-ray beam modulator two or more arrays of modulator elements, 92, 94, aligned in series, two of which are shown in FIG. 12. For clarity of the arrangement, details of each modulator element in each array are not included in FIG. 12, and the output barrier wall or walls is not shown, but is to be understood to be included. A number of arrays of modulator elements can be aligned in series, and in embodiments herein, at least two or more arrays of modulator elements are aligned in series. In the example arrangement of two arrays of modulator elements shown in FIG. 12, an input x-ray beam 22 is directed to a first array of modulator elements 92, having surface layers oriented at a first selected angle or a variety of first angles, for a first modulation event. The interaction of the input x-ray beam 22 with the first array of modulator elements 92 produces a first set of x-ray beamlets, 96, each having a modulated x-ray beam intensity corresponding to the first selected angle or variety of first angles.

The beamlets 96 are directed to the second array of modulator elements 94, which separately and distinctly from the first array of elements 92, has surface layers oriented at a selected second angle or a range of second angles, for a second modulation event. The interaction of the x-ray beamlets 96 with the second array of modulator elements 94 produces modulator output beamlets 28, each having a modulated x-ray beam intensity corresponding to the selected second angle. As a result, the input x-ray beam 22 is here modulated by a combination of two or more distinct and separate modulation events, enabling the fine tuning and precise quasi-continuous modulation of the input x-ray beam intensity, to produce output x-ray beams having selected intensities.

As explained above, in embodiments herein, a modulator element includes one or more material regions that extend over and are suspended across an indentation in a lower substrate region, thereby providing a suspended modulator element. In example embodiments described above, at least one material region spans the lateral extent of an indentation as a suspended bridge, or doubly-supported beam structure, and carries one or more upper layers that span at least a portion of the lateral indentation extent. The suspended bridge structure is not required; other suspended structures can be employed.

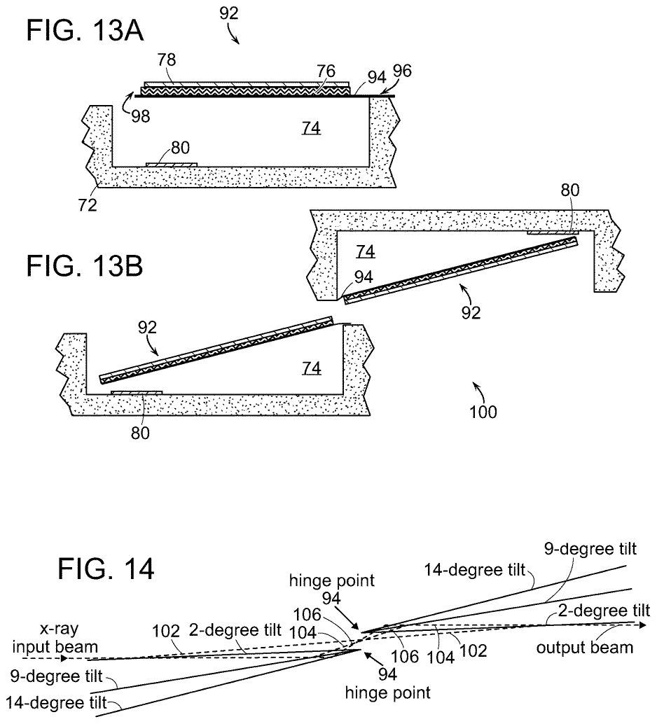

In a further embodiment of such, referring to FIG. 13, a modulator element is implemented as a suspended cantilever beam 92 including a suspended region spanning at least a portion of the lateral extent of an indentation 74 in a substrate 72. The cantilever beam 92 includes one or more layers of material and/or material regions. In one embodiment, the cantilever beam includes a lower material layer 94 one lateral end of which extends over the edge of the indentation 74 to form a cantilever hinge point 96 at the edge of the indentation 74. The other lateral edge 98 of the cantilever beam is free to move in the vertical direction. One or more upper layers 76, 78 of the cantilever beam span at least a portion of the lateral indentation extent. With this arrangement, the free end 98 of the cantilever beam is vertically tiltable around the hinge point 96 and can be tilted downward into the indentation 74 by applying a voltage to the electrode 80. Control of the voltage on the electrode by a controller thereby enables a wide range of cantilever tilt angles, between zero and a maximum angle, set by the depth of the indentation 74. The top-most layer of cantilever material is that material selected for reflection of an input x-ray beam. This cantilevered modulator element can be disposed in an array of cantilevered modulator elements as in the array of doubly supported beams shown in FIG. 7.

One skilled in the art will recognize the range of materials suitable for producing suspended bridge structures and suspended cantilever beams for the modulator elements. For example, such cantilevered beams are widely used in commercially available scanning force microscopes. In one embodiment, a bridge or beam structure is formed of a low-stress silicon nitride composition, or is formed of diamond, or is formed of another suitable material, preferably that enforces a substantially flat exposed surface. Tensile or compressive stress in the bridge and beam materials can cause a bridge or beam to curl away from flatness. Well-known methods and equipment for producing a range of materials, and particularly silicon nitride compositions, that are substantially free of stress and the resulting structural curvature are well known and understood. In one example, a thin hinge layer 94 is provided as low-stress silicon nitride, or other suitable material. Atop the hinge layer 94 there are included in embodiments herein a structural support layer 76 corresponding to the lower layer of the suspended bridge structure described above. The top layer 78 is the selected x-ray beam reflection layer, such as a layer of uranium of 10 nanometers or greater thickness to enable efficient grazing-incidence reflection of an incident x-ray beam of 4.5 nm wavelength, or a layer of molybdenum of 20 nanometers or greater thickness to enable efficient grazing incidence reflection of an incident x ray beam of 13.5 nm wavelength.

Assuming a cantilever beam width of approximately 20 micrometers, in correspondence with a microlens width of 20 micrometers, then an input x-ray beam grazing angle of 2 degrees prescribes an elongated region along the length of the cantilever from which the output beam emerges of 20 micrometers divided by the sine of the grazing angle, here 2 degrees, giving a reflecting cantilever length of 573 micrometers. Grazing incidence angles smaller than 2 degrees require longer cantilever regions while larger grazing angles require shorter cantilever regions.

Referring to the data of FIG. 3, a grazing angle of 2 degrees onto a 10 nm-thick film of uranium yields a reflectivity of 96% for a 4.5 nm-wavelength x-ray beam. Given a desirability in general to limit the length of modulator element cantilever beams in an effort to maintain cantilever flatness while also maximizing reflectivity, those skilled in the art will recognize the angle of 2 degrees as being a reasonable minimum grazing angle. For this embodiment, it is therefore preferred that the cantilever beam have a length of between about 575 micrometers and about 590 micrometers. For the doubly supported bridge spans, flatness is enforceable by imposing sufficient tension in the material in known material compositions; as indicated above, control of the tension in deposited silicon nitride material is well known to those skilled in the art.

Referring to FIG. 13B, in other embodiments herein, there is provided a compound modulator element including an aligned pair 100 of cantilevered modulator elements, each implemented as a suspended cantilever beam 92, having layers such as those shown in FIG. 13A. In these embodiments, each of the two cantilever elements 92 is controlled by a corresponding electrode 80 to have substantially the same tilt angle, so that the top surfaces are parallel with each other, as represented in FIG. 13B. With a corresponding distance between the two cantilever beam elements 92, an x-ray beam incident on a first of the two beam elements is reflected to the second of the two beam elements and then reflected as an output x-ray beam having an intensity that has been modulated by both of the two cantilever beam elements. Given that the two elements have the same cantilever tilt angle, then each of the two elements imposes the same degree of intensity modulation.

An important advantage provided by the compound modulator element pair 100 is an ability to produce an output x-ray beam having the same direction as the input x-ray beam and having an elevation that is independent of the angle to which the cantilevers are tilted. This is true for any cantilever beam tilt angle imposed on the pair 100. This geometry is illustrated schematically in FIG. 14, showing three different cantilever beam tilt angles, namely, a 2-degree tilt, a 9-degree tilt, and a 14-degree tilt; here a single straight line geometrically represents a cantilever beam tilted at a given angle. The 2-degree, 9-degree, and 14-degree cantilever beam tilts shown here are three separate cantilever beam configurations, only one of which can be taken on at a given time. The hinge point 94 of each cantilever beam is shown for each of the three tilt position orientations. The figure illustrates three cantilever beams for descriptive purposes only. The input x-ray beam is depicted as a dashed line in its path toward the cantilever beam pair; with a first trajectory 102 produced by a 2-degree tilted cantilever beam, a second trajectory 104 produced by a 9-degree tilted cantilever beam, and a third trajectory 106 produced by a 14-degree tilted cantilever beam. As shown in FIG. 14, the location and direction of the output x-ray beam is the same for all of the tilt angles, and the direction is the same as that of the input x-ray beam. The resulting constancy of the output x-ray beam location and direction is independent of tilt angle as long as the tilt angles of both cantilever beams in the pair are the same.

With the x-ray beam trajectory represented in FIG. 14 for a matched pair of cantilever beam modulator elements, an x-ray beam undergoes two reflections at the same angle while traversing the pair. The intensity of the x-ray beam output from the pair is thereby reduced by the square of the fractional reflection from a single surface. Considering this condition for an example of a reflective uranium surface layer, and assuming a radiation wavelength of 4.5 nanometers and substantially flat reflective surfaces, then for a tilt angle of 2 degrees for each cantilever beam of the matched pair, the intensity of an output x-ray beam is reduced to 92% of the input x-ray beam intensity. For matching tilt angles of 9 degrees, the intensity of an output x-ray beam is reduced to about 50% of the input x-ray beam intensity, and for matching tilt angles of 14 degrees, the intensity of an output x-ray beam is about 0.1% of the input x-ray beam intensity. This modulation determination is based solely on geometry and known properties of uranium illuminated at 4.5 nm wavelength; it can be preferred to include the effects of other sources of intensity loss in the modulator elements of a given modulator system to determine the modulation properties of a modulator system. Modulator system characterization, with experimental measurement of modulation properties, can also be used to calibrate and control a modulator system in conjunction with mathematical modulation determination.

Referring back to FIG. 13, each cantilever beam 92 in the modulator pair 100 is in embodiments herein actuated electrostatically, with, e.g., an electrically conducting electrode 80. In other embodiments, actuation of a modulator element, whether implemented as a cantilever beam, doubly supported bridge, or other arrangement, is enabled with another selected actuator, such as a piezoelectric driver. The piezoelectric driver is controlled by a controller such as the controller 30 (FIG. 1) and/or a controller within the modulator 10.

Referring to FIG. 15, in one embodiment of such, a compound modulator element pair 110 of doubly supported reflective beams is arranged, e.g., as a support beam layer 112 underpinning a top reflecting layer 114, such as a layer of uranium atop a layer of silicon nitride, in conjunction with 4.5 nanometer radiation, or a layer of molybdenum in conjunction with 13.5 nanometer radiation. A piezoelectric driver element 116 is disposed at each end of the beam layers 112, 114, holding the layers suspended over a support substrate 118. Electrical control of each piezoelectric driver element 116 controls elevation of each doubly supported beam and the surface of reflection of each beam. In turn, the piezoelectric actuation of the layers controls the angle of incidence between an input x-ray beam and each reflection surface, to produce a selected modulation in the intensity of the output x-ray beam. Piezoelectric driver elements can be particularly preferred in many applications due to their characteristically high-speed actuation and high degree of actuation precision. Such is exploited in embodiments herein with separate control of each piezoelectric driver element 116, enabling fine adjustment of incident angle for high-resolution control of x-ray beam intensity modulation and output direction.

As shown in FIG. 15, under a preferable condition in which both doubly supported beams in the pair 110 are actuated to have the same angle, such that the reflecting plane of each of the two beams are parallel to each other, then the output x-ray beam has the same angular orientation of the input x-ray beam, for any selected angle, in the manner described with reference to the cantilever beam elements of FIG. 13. In one example of such, as represented in FIG. 15, with a input x-ray beam grazing angle of 10 degrees, corresponding to an incident angle of 80 degrees, then based on the properties of a uranium reflecting layer, as depicted in FIG. 3, the compound modulator element 110 reduces the intensity of the output x-ray intensity to about 25% of the input beam intensity for the case of x-radiation of 4.5 nanometer wavelength.

The gaseous environment in which the x-ray beam intensity modulator elements, such as an array or arrays of modulator elements, are disposed is preferably controlled with consideration for the selected modulator materials. For example, thermal conduction and convection of input x-ray beam power that is absorbed into a modulator element material, rather than reflected off of the material surface, is preferably considered. Such thermal control is achieved herein preferably with a helium or hydrogen atmosphere. For modulation applications processing a 4.5 nm-wavelength input x-ray beam, a helium atmosphere is preferred for the intensity modulator environment, to enable superior convection of x-ray beam power that is absorbed from an input x-ray beam. For modulation applications processing a 13.5 nm-wavelength input x-ray beam, a hydrogen atmosphere is preferred. In other considerations, in embodiments employing a uranium layer, the uranium surface reactivity is preferably taken into consideration.

Referring back to FIG. 1, considering other aspects of a maskless x-ray lithography system 12 including the x-ray beam modulator 10, an input x-ray beam 22 to be processed by the modulator 10 is provided by a suitable source 14 such as an undulator, a free-electron laser, a source based on so-called high-harmonic generation, or other suitable source, including any suitable commercially-available x-ray beam generator. The x-ray beams from undulators, free-electron lasers and high-harmonic generation tend to be well collimated, with a spectral bandwidth of the order of 1%, and therefore are preferred for most applications.

Diffractive-optical microlenses 36 in the lens array 34 of the lithography system 12 include Fresnel zone plates, Fresnel lenses or so-called metalenses, all of which utilize the phenomenon of diffraction to form focal spots or non-circular distributions such as focal lines. The spectral bandwidth of the x-ray beam source determines the design of diffractive-optical microlenses in a manner understood by those skilled in the art. For example, with an x-ray beam source spectral bandwidth of 1% around a central wavelength, the number of zones of a Fresnel zone plate, Fresnel lens or metalens to be employed in the lithography system provided herein is in one embodiment preferably limited to about 100, to avoid so-called chromatic aberration. This, together with the wavelength and desired focal size of the x-ray beam at the surface of a layer of resist, dictates the size of the diffractive optical microlens to be employed in the lithography system.

Thus, given an x-ray beam source, such as a free-electron laser, with a spectral bandwidth of 1% and a wavelength of 4.5 nm, and given a desired focal spot size of about 10 nm, then the requisite diameter of each microlens 36 is about 20 micrometers. As a result, as explained above, the diameter of an x-ray beam output from the modulator 10 and impinging on a microlens need be no larger than about 20 micrometers. These dimensions, while not implying a restriction or limitation, are provided as an example of one embodiment, for understanding the relationships among the x-ray beam wavelength, the x-ray source bandwidth, the desired focal size of a beam impinging on a layer of resist, the dimensions of a single output beam of the modulator, and the microlens parameters that focus the x-ray beam output from the modulator 10.

It is well known and understood by those skilled in the art that in addition to producing circular focal spots, diffractive optical microlenses can also produce non-circular focal spots and focal lines. If, for example, the zones of a diffractive-optical microlens have elliptical shapes the focal spot can have an elliptical shape. The x-ray beam intensity modulator provided herein is applicable to any of the various forms of diffractive optical microlenses and hence to the production of variable intensity elliptical foci and line foci.

With this description it is demonstrated that the x-ray beam intensity modulator, modulator elements, and modulation methods provided herein, achieve highly efficient, effective x-ray beam intensity control heretofore unachievable for radiation wavelengths between 1 nm and 20 nm, providing the ability to harness the use of soft x-rays in advanced lithography for the production of nanometric features required by any in a wide range of applications including electronics, medicine, materials, and communications.

We claim:

1. A maskless x-ray lithography system comprising:
a source of an input x-ray beam having a wavelength between 1 nm and 20 nm;
an x-ray beam intensity modulator including a plurality of x-ray beam intensity modulator elements, each x-ray beam intensity modulator element having an x-ray-reflective surface oriented with respect to the input x-ray beam at an x-ray beam grazing angle greater than zero degrees and no larger than an extinguishing grazing angle at which reflectivity is substantially zero for the input x-ray beam wavelength and x-ray-reflective surface material, to produce a plurality of output x-ray beams each having an output intensity that is a fraction of input intensity of the input x-ray beam; and
a plurality of microlenses, each microlens oriented to focus a modulated output x-ray beam from the x-ray beam intensity modulator, the plurality of microlenses together producing a plurality of focused, intensity-modulated x-ray beams to form a lithographic pattern.

2. The maskless x-ray lithography system of claim 1 wherein the x-ray-reflective surface of each modulator element comprises a material selected from uranium, a uranium alloy, gold, cobalt, and molybdenum.

3. The maskless x-ray lithography system of claim 1 wherein each x-ray beam intensity modulator element includes a mechanically moveable structure comprising the x-ray-reflective surface to orient the x-ray-reflective surface with respect to an input x-ray beam at an x-ray beam grazing angle greater than zero degrees and no larger than an extinguishing grazing angle at which reflectivity is substantially zero for the input x-ray beam wavelength and x-ray-reflective surface material.

4. The maskless x-ray lithography system of claim 3 wherein the mechanically moveable structure of each x-ray beam intensity modulator element comprises a support material disposed under an x-ray-reflective material having the x-ray-reflective surface to orient the x-ray-reflective surface with respect to an input x-ray beam at an x-ray beam grazing angle greater than zero degrees and no larger than an extinguishing grazing angle at which reflectivity is substantially zero for the input x-ray beam wavelength and x-ray-reflective surface material.

5. The maskless x-ray lithography system of claim 1 wherein each x-ray beam intensity modulator element includes an actuation element selected from piezoelectric actuation elements and electrostatic actuation elements to orient the x-ray-reflective surface with respect to an input x-ray beam at an x-ray beam grazing angle greater than zero degrees and no larger than an extinguishing grazing angle at which reflectivity is substantially zero for the input x-ray beam wavelength and x-ray-reflective surface material.

6. The maskless x-ray lithography system of claim 1 wherein at least two of the x-ray beam intensity modulator elements, in the plurality of x-ray beam intensity modulator elements, each have an x-ray-reflective surface oriented with respect to the input x-ray beam at a different x-ray beam grazing angle greater than zero degrees and no larger than an extinguishing grazing angle at which reflectivity is substantially zero for the input x-ray beam wavelength and x-ray-reflective surface material.

7. The maskless x-ray lithography system of claim 1 wherein the x-ray-reflective surface of each x-ray beam intensity modulator element comprises an x-ray-reflective surface having a vertically undulating surface profile with periodically spaced undulations along an extent of the x-ray-reflective surface, portions of the periodically spaced undulations being oriented with respect to the input x-ray beam at an x-ray beam grazing angle greater than zero degrees and no larger than an extinguishing grazing angle at which reflectivity is substantially zero for the input x-ray beam wavelength and x-ray-reflective 9 surface material.

1. 8. The maskless x-ray lithography system of claim 1 wherein the array of 2 microlenses comprises an array of microlenses selected from Fresnel zone 3 plates, Fresnel lenses, refractive lenses, and metalenses.

1. 9. The maskless x-ray lithography system of claim 1 wherein:

2. the source of an input x-ray beam comprises a source of a substantially 3 collimated input x-ray beam having a wavelength centered at 13.5 nm; and

4. the x-ray-reflective surface of the modulator element comprises a 5 surface of a layer of molybdenum.

1. 10. The maskless x-ray lithography system of claim 1 wherein:

2. the source of an input x-ray beam comprises a source of a substantially 3 collimated input x-ray beam having a wavelength centered at 4.5 nm; and

4. the x-ray-reflective surface of the modulator element comprises a 5 surface of a layer selected from uranium and a uranium alloy.

1. 11. An x-ray beam intensity modulator comprising:

2. an input port oriented to accept an input x-ray beam having an x-ray 3 beam wavelength between 1 nm and 20 nm;

4. a plurality of x-ray beam intensity modulator elements, each x-ray beam 5 intensity modulator element having an x-ray-reflective surface oriented with 6 respect to the input x-ray beam at an x-ray beam grazing angle greater than 7 zero degrees and no larger than an extinguishing grazing angle at which 8 reflectivity is substantially zero for the input x-ray beam wavelength and x-ray-9 reflective surface material, to produce a plurality of output x-ray beams each having a modulated output intensity that is a fraction of input intensity of an input x-ray beam; and
an output port oriented to output a plurality of intensity-modulated output x-ray beams.

1. 12. The x-ray beam intensity modulator of claim 11 wherein the x-ray-2 reflective surface of each x-ray beam intensity modulator element comprises a 3 material selected from uranium, a uranium alloy, gold, cobalt, and 4 molybdenum.

1. 13. The x-ray beam intensity modulator of claim 11 wherein each x-ray 2 beam intensity modulator element includes an actuation element, selected 3 from piezoelectric actuation elements and electrostatic actuation elements, to 4 orient the x-ray-reflective surface with respect to the input x-ray beam at an x-5 ray beam grazing angle greater than zero degrees and no larger than an 6 extinguishing grazing angle at which reflectivity is substantially zero for the 7 input x-ray beam wavelength and x-ray-reflective surface material, to produce 8 a reflected output x-ray beam having an output intensity that is a fraction of 9 input intensity of the input x-ray beam.

1. 14. The x-ray beam intensity modulator of claim 11 wherein the x-ray-2 reflective surface of each x-ray beam intensity modulator element comprises 3 an x-ray-reflective surface having a vertically undulating surface profile with 4 periodically spaced undulations along an extent of the x-ray-reflective surface, 5 portions of the periodically spaced undulations being oriented with respect to 6 the input x-ray beam at an x-ray beam grazing angle greater than zero 7 degrees and no larger than an extinguishing grazing angle at which reflectivity 8 is substantially zero for the input x-ray beam wavelength and x-ray-reflective 9 surface material, to produce modulated output x-ray beams including at least one of a plurality of zero-order x-ray diffraction beams and a plurality of non-zero order x-ray diffraction beams, each modulated output x-ray beam having an output intensity that is a fraction of input intensity of the input x-ray beam.

1. 15. An x-ray beam intensity modulator comprising:

2. an input port oriented to accept an input x-ray beam having an x-ray 3 beam wavelength between 1 nm and 20 nm;

4. a plurality of x-ray beam intensity modulator elements, each x-ray beam 5 intensity modulator element including an x-ray-reflective surface having a 6 vertically undulating surface profile with periodically spaced undulations along 7 an extent of the x-ray-reflective surface, portions of the periodically spaced 8 undulations being oriented with respect to the input x-ray beam at an x-ray 9 beam grazing angle greater than zero degrees and no larger than an extinguishing grazing angle at which reflectivity is substantially zero for the input x-ray beam wavelength and x-ray-reflective surface material, to produce modulated output x-ray beams including at least one of a plurality of zero-order x-ray diffraction beams and a plurality of non-zero order x-ray diffraction beams, each modulated output x-ray beam having an output intensity that is a fraction of input intensity of the input x-ray beam; and
an output port oriented to output a plurality of intensity-modulated output x-ray beams.

1. 16. The x-ray beam intensity modulator of claim 15 wherein the x-ray-2 reflective surface of each x-ray beam intensity modulator element comprises a 3 material selected from uranium, a uranium alloy, gold, cobalt, and 4 molybdenum.

1. 17. A method for maskless x-ray lithographic patterning of a surface 2 comprising:

3. providing an input x-ray beam having a wavelength between 1 nm and 4 20 nm;

5. directing the input x-ray beam toward a plurality of x-ray-reflective 6 surfaces, each x-ray-reflective surface having a vertically undulating surface

7. profile with periodically spaced undulations along an extent of the x-ray-8 reflective surface;

9. orienting portions of the periodically spaced undulations with respect to the input x-ray beam at an x-ray beam grazing angle greater than zero degrees and no larger than an extinguishing grazing angle at which reflectivity is substantially zero for the input x-ray beam wavelength and x-ray-reflective surface material, to produce modulated output x-ray beams including at least one of a plurality of zero-order x-ray diffraction beams and a plurality of non-zero order x-ray diffraction beams, each modulated output x-ray beam having an output intensity that is a fraction of input intensity of the input x-ray beam;
and directing the plurality of modulated output x-ray beams to an array of microlenses oriented to focus the modulated output x-ray beams onto a surface in a lithographic pattern of intensity-modulated x-ray beams, for forming a lithographic pattern on the surface.

1. 18. The method of claim 17 wherein at least two x-ray-reflective surfaces in 2 the plurality of x-ray-reflective surfaces have surface portions that are oriented 3 with respect to the input x-ray beam at x-ray beam grazing angles different 4 than that of other x-ray-reflective surfaces.

1. 19. A method for maskless x-ray lithographic patterning of a surface 2 comprising:

3. providing an input x-ray beam having a wavelength centered at 13.5 nm;

5. directing the input x-ray beam toward a plurality of separated 6 molybdenum surfaces, each molybdenum surface oriented with respect to the 7 input x-ray beam at an x-ray beam grazing angle greater than zero degrees 8 and no larger than an extinguishing angle of 27 degrees, at which reflectivity is 9 substantially zero for the input x-ray beam wavelength, to produce a plurality

10. of modulated output x-ray beams each having an output intensity that is a 11 fraction of input intensity of the input x-ray beam; and

12. directing the plurality of modulated output x-ray beams to a plurality of 13 microlenses oriented to focus the modulated output x-ray beams onto a 14 surface in a lithographic pattern of intensity-modulated x-ray beams, for 15 forming a lithographic pattern on the surface.

1. 20. A method for maskless x-ray lithographic patterning of a surface 2 comprising:

3. providing an input x-ray beam having a wavelength centered at 4.5 nm;

4. directing the input x-ray beam toward a plurality of separated x-ray-5 reflective surfaces, each x-ray reflective surface comprising uranium and 6 oriented with respect to the input x-ray beam at an x-ray beam grazing angle 7 between zero degrees and no more than an extinguishing grazing angle of 13 degrees, at which reflectivity is substantially zero for the input x-ray beam 9 wavelength, to produce a plurality of modulated output x-ray beams each 10 having a modulated output intensity that is a fraction of input intensity of the 11 input x-ray beam; and

12. directing the plurality of modulated output x-ray beams to an array of 13 microlenses oriented to focus the modulated output x-ray beams onto a 14 surface in a lithographic pattern of intensity-modulated x-ray beams, for 15 forming a lithographic pattern on the surface.
